(19) United States
(12) Patent Application Publication
(10) Pub. No.: US 2023/0420636 A1
(43) Pub. Date: Dec. 28, 2023

(54) SILICON-CONTAINING MATERIALS

(71) Applicant: WACKER CHEMIE AG, Munich (DE)

(72) Inventors: Christoph Dräger, München (DE); Eckhard Hanelt, Geltendorf (DE); Alena Kalyakina, München (DE); Claudia Kleinlein, Burghausen (DE)

(73) Assignee: Wacker Chemie AG, Munich (DE)

(21) Appl. No.: 18/037,090

(22) PCT Filed: Nov. 30, 2020
(86) PCT No.: PCT/EP2020/083890

§ 371 Date: May 16, 2023

(51) Int. Cl. H01M 4/04; H01M 10/0525; H01M 4/38

(52) U.S. Cl. CPC H01M 4/0471; H01M 10/0525; H01M 4/0402; H01M 4/386; H01M 2004/021

(57) ABSTRACT

A silicon-containing material along with processes for producing and uses for the same. Where the silicon-containing material is based on one or more porous particles and silicon and the silicon is disposed in pores and on the surface of the one or more porous particles. The silicon-containing material has a specific surface area of at most 50 m²/g, determined by nitrogen sorption and BET evaluation and the one or more porous particles have a mean electrical particle resistance of at least 2 kOhm and a reversible delithiation capacity 0 of at most 100 mAh/g.

The present invention relates to silicon-containing materials based on porous particles and silicon, to processes for producing the silicon-containing materials and to the use thereof as active materials in anodes for lithium-ion batteries.

As storage media for electric current, lithium-ion batteries are currently the practical electrochemical energy storage devices with the highest energy densities. Lithium-ion batteries are mainly used in the field of portable electronics, for tools and also for electrically powered means of transport such as bicycles, scooters or automobiles. Graphitic carbon is currently widely used as the active material for the negative electrode (“anode”) of corresponding batteries. A disadvantage, however, is the relatively low electrochemical capacity of such graphitic carbons, which is theoretically at most 372 mAh per gram of graphite and thus corresponds to only about one tenth of the electrochemical capacity that can theoretically be achieved with lithium metal. Alternative active materials for the anode use a silicon addition, as described for example in EP 1730800 B1, U.S. Pat. Nos. 10,559,812 B2, 10,819,400 B2, or EP 3335262 B1. Silicon forms binary electrochemically active alloys with lithium, allowing very high electrochemically achievable lithium contents of up to 3579 mAh per gram of silicon [M. Obrovac, V. L. Chevrier Chem. Rev. 2014, 114, 11444].

The incorporation and removal of lithium ions in silicon is associated with the disadvantage that a very high volume change occurs, which can reach up to 300% in the case of complete incorporation. Such changes in volume subject the silicon-containing active material to severe mechanical stress, as a result of which the active material may eventually break apart. This process, also referred to as electrochemical grinding, leads to a loss of electrical contact in the active material and in the electrode structure and thus to a lasting, irreversible loss of the capacity of the electrode.

Furthermore, the surface of the silicon-containing active material reacts with constituents of the electrolyte with continuous formation of passivating protective layers (Solid Electrolyte Interphase; SEI). The components formed are no longer electrochemically active. The lithium bound therein is no longer available to the system, thus leading to a pronounced continuous loss of battery capacity. Due to the extreme change in volume of the silicon during the charging and discharging process of the battery, the SEI regularly ruptures, which exposes further unoccupied surfaces of the silicon-containing active material, which are then exposed to further SEI formation. Since the amount of mobile lithium in the full cell, which corresponds to the usable capacity, is limited by the cathode material, this is increasingly consumed and the capacity of the cell decreases to an unacceptable extent from an application point of view after only a few cycles.

The decrease in capacity over the course of several charging and discharging cycles is also referred to as fading or continuous loss of capacity and is usually irreversible.

A series of silicon-carbon composite particles have been described as active materials for lithium-ion battery anodes, in which the silicon is incorporated into porous carbon particles starting from gaseous or liquid precursors. For example, U.S. Pat. No. 10,147,950 B2 describes the deposition of silicon from monosilane SiH₄ in a porous carbon in a tube furnace or comparable furnace types at elevated temperatures of 300 to 900° C., preferably with agitation of the particles by a CVD (“chemical vapor deposition”) or PE-CVD (“plasma-enhanced chemical vapor deposition”) process. An analogous procedure is described in U.S. Pat. No. 10,424,786 B1, in which the silicon precursors are introduced as a mixture with inert gas ata total pressure of 1.013 bar. WO2012/097969 A1 describes the deposition of ultra-fine silicon particles in the range of 1 to 20 nm by heating silanes as silicon precursors on porous carbon supports at 200 to 950° C., the silane being diluted with an inert gas to prevent agglomeration of the deposited silicon particles or the formation of thick layers, the deposition taking place in a pressure range of 0.1 to 5 bar.

The silicon-containing materials accessible from the described processes have in common that when the silicon-containing material is used as active material in anodes for lithium-ion batteries, carbon also contributes to some extent to the electrochemical capacity of the silicon-containing materials in addition to the silicon. Due to the amorphous structure of the carbons used in most cases, a disproportionately large amount of lithium remains in the silicon-containing material during electrochemical cycling in a restricted potential window, which, especially in the case of application in mobile phones, does not encompass the completely theoretically possible range, and is not available for further cycling (“trapping”). Thus, the total capacity cannot be used, which is disadvantageous for the use of the known silicon-containing materials in such applications.

In addition, it is disadvantageous that the deposition of the silicon at temperatures above circa 800° C. is only possible to a limited extent, since the formation of silicon carbide can occur due to the high reactivity of the amorphous carbon to gaseous silicon precursors, which can greatly reduce the capacity of the silicon-containing materials for storing lithium ions, since silicon carbide, unlike silicon, cannot be used for electrochemical storage of lithium ions. Furthermore, at these high temperatures, there is the risk that at least part of the porosity of the porous particles will be lost due to sintering processes.

U.S. Pat. No. 9,005,818 B2 describes silicon-containing anode active materials for lithium-ion batteries, which are obtained by depositing silicon from gaseous silicon precursors into a mesoporous silicon dioxide matrix. The product thus obtained contains silicon in an amount of 0.05 to 100%, based on the weight of the mesoporous silicon dioxide matrix, and has a pore volume of 0.2 to 0.5 ml/g as determined by nitrogen sorption and BET surfaces of 150 to 1000 m²/g. The initial Coulomb efficiency and the cycling stability of corresponding lithium-ion batteries are not yet satisfactory.

Against this background, the object was to provide silicon-containing materials which, when used as active materials in anodes of lithium-ion batteries, exhibit a low initial and continuous loss of lithium available in the cell and thus enable high Coulomb efficiencies and, in addition, stable electrochemical behavior in the subsequent cycles. The fading or trapping should preferably be as small as possible.

Surprisingly, this object was able to be achieved using silicon-containing materials based on one or more porous particles and silicon, wherein the silicon is disposed in pores and on the surface of the porous particles and the silicon-containing materials have a specific surface area of at most 50 m²/g, determined by nitrogen sorption and BET evaluation, characterized in that the porous particles have a mean electrical particle resistance of at least 2 kOhm and a reversible delithiation capacity β of at most 100 mAh/g. This is particularly surprising since active materials for lithium-ion batteries, which have low electronic conductivity and thus high electrical particle resistance, are usually provided with an electronically conductive layer of carbon, for example, which has a very low electronic resistance. This is known, for example, for the lithium iron phosphate used as cathode active material, for example in EP 3 678 990 A1, or also for the silicon suboxide SiOx used as the anode active material, for example from EP 1 323 783 B1. In this respect, it is generally assumed that the average particle resistance of porous particles as starting material for silicon-containing materials for use as active material in anodes of lithium-ion batteries should be less than 2 kOhm in order to allow full utilization of the capacity of such silicon-containing materials and the necessary conductivity within the electrode. Typically, porous carbons have such low particle resistivities. In contrast, it has now been surprisingly found that even with a mean electrical particle resistance of the porous particles of more than 2 kOhm, the electrical conductivity of the resulting silicon-containing material is sufficient to make the full capacity usable in the application as an active material in anodes of lithium-ion batteries.

The invention relates to a silicon-containing material based on one or more porous particles and silicon, wherein the silicon is disposed in pores and on the surface of the porous particles and the silicon-containing material has a specific surface area of at most 50 m²/g, determined by nitrogen sorption and BET evaluation, characterized in that the porous particles have

a) a mean electrical particle resistance of at least 2 kOhm and

b) a reversible delithiation capacity β of at most 100 mAh/g.

The porous particles that can be used for the silicon-containing materials are any materials, the particles of which have an average electrical particle resistance of at least 2 kOhm and have a reversible delithiation capacity β of at most 100 mAh/g, preferably to 100 mAh/g, particularly preferably 2 to 80 mAh/g.

Preference is given here to oxides such as silicon dioxide, aluminum oxide, silicon-aluminum mixed oxides, magnesium oxide, lead oxides and zirconium oxide; carbides such as silicon carbides and boron carbides; nitrides such as silicon nitrides and boron nitrides; and other ceramic materials as can be described by the following component formula:

AlₐB_{b}C_{c}Mg_{d}NeO_{f}Si_{g} where 0 £ a, b, c, d, e, f, g≤1; with at least two coefficients a to g >0 and a*3+b*3+c*4+d*2+g*4 ³ e*3+f*2.

The ceramic materials can be, for example, binary, ternary, quaternary, quinary, senary or septernary compounds. Preference is given to ceramic materials having the following component formulae:

non-stoichiometric boron nitrides BN_{z} where z=0.2 to 1,

non-stoichiometric carbon nitrides CN_{z} where z=0.1 to 4/3,

boron carbonitrides BₓCN_{z} where x=0.1 to 20 and z=0.1 to 20, where x*3+4 ³ z*3,

boron nitride oxides BN_{z}Oᵣ where z=0.1 to 1 and r=0.1 to 1, where 3 ³ r*2+z*3,

boron carbonitride oxides BₓCN_{z}Oᵣ where x=0.1 to 2, z=0.1 to 1 and r=0.1 to 1, where x*3+4 ³ r*2+z*3,

silicon carbon oxides SiₓCO_{z} where x=0.1 to 2 and z=0.1 to 2, where x*4+4 ³ z*2,

silicon carbonitrides SiₓCN_{z} where x=0.1 to 3 and z=0.1 to 4, where x*4+4 ³ z*3,

silicon boron carbonitrides Si_{w}BₓCN_{z} where w=0.1 to 3, x=0.1 to 2 and z=0.1 to 4, where w*4+x*3+4 ³ z*3,

silicon boron carbon oxides Si_{w}BₓCO_{z} where w=0.10 to 3, x=0.1 to 2 and z=0.1 to 4, where w*4+x*3+4 ³ z*2,

silicon boron carbonitride oxides SiᵥB_{w}CNₓO_{z} where v=0.1 to 3, w=0.1 to 2, x=0.1 to 4 and z=0.1 to 3, where v*4+w*3+4 ³ x*3+z*2 and

aluminum boron silicon carbonitride oxides AlᵤBᵥSiₓCN_{w}O_{z} where u=0.1 to 2,v=0.1 to 2, w=0.1 to 4, x=0.1 to 2 and z=0.1 to 3, where u*3+v*3+x*4+4 ³ w*3+z*2.

Preferred porous particles are based on silicon dioxide, boron nitride, silicon carbide, silicon nitride or on mixed materials based on these compounds, in particular on silicon dioxide or boron nitride.

Especially preferred porous particles are porous boron nitride particles, in particular porous silicon oxide particles, particular preference being given to nanoporous silicon oxide particles.

The synthesis of the porous particles can generally be based on sol-gel syntheses, such as described, for example, for silica gels, aerogels or xerogels by M. Kato, K. Sakai-Kato, T Toyo'oka, J. Sep. Science, 2005, 28, 1893-1908. SiO₂ materials having pore structures in the size range of less than 10 nm and at the same time high pore volume are preferably prepared using sol-gel processes using very small basic units (SiO₂ particles, Polyhedral Oligomeric Silsesquioxane (POSS) units). The pore characteristics can be adjusted, for example, via the reaction conditions, such as temperature, type of catalyst and concentration, or also the silane functionalization. Other influencing factors are, for example, the drying conditions of the gel or post-treatment thereof, such as annealing. Porosities above 90% at pore sizes smaller than 100 nm are accessible, for example, by supercritical drying of the gel. Xerogels having pore sizes below 10 nm can also be obtained by convective drying.

The porous particles preferably have a density, determined by helium pycnometry, of 0.1 to 7 g/cm³ and particularly preferably of 0.3 to 3 g/cm³. This is advantageous for increasing the gravimetric capacity (mAh/cm³) of lithium-ion batteries.

The porous particles have a volume-weighted particle size distribution with diameter percentiles dso of preferably ≥0.5 μm, particularly preferably ≥1.5 μm and most preferably ≥2 μm. The diameter percentiles d₅₀ are preferably ≤20 μm, more preferably 12 μm and most preferably ≤8 μm.

The volume-weighted particle size distribution of the porous particles is preferably between the diameter percentiles d₁₀≥0.2 μm and d₉₀≤20.0 μm, particularly preferably between d₁₀≥0.4 μm and d₉₀≤15.0 μm and most preferably between d₁₀≤0.6 μm to d₉₀≤12.0 μm.

The porous particles have a volume-weighted particle size distribution with diameter percentiles d₁₀ of preferably ≤10 μm, particularly preferably ≤5 μm, especially preferably ≤3 μm and most preferably ≤2 μm. The diameter percentiles d₁₀ are preferably ≥0.2 μm, particularly preferably ≥0.5 μm and most preferably ≥1 μm.

The porous particles have a volume-weighted particle size distribution with diameter percentiles d₉₀ of preferably ≥4 μm and particularly preferably ≥8 μm. The diameter percentiles d₉₀ are preferably ≤18 μm, more preferably ≤15 μm and most preferably ≤13 μm.

The volume-weighted particle size distribution of the porous particles has a width d₉₀-d₁₀ of preferably ≥15.0 μm, more preferably ≥12.0 μm, particularly preferably ≤10.0 μm, especially preferably ≤8.0 μm and most preferably ≤4.0 μm. The volume-weighted particle size distribution of the porous particles has a width d₉₀-d₁₀ of preferably ≥0.6 μm, particularly preferably ≥0.7 μm and most preferably ≥1.0 μm.

The volume-weighted particle size distribution can be determined according to ISO 13320 using static laser scattering using the Mie model with the Horiba LA 950 measuring device with ethanol as the dispersing medium for the porous particles.

The porous particles can be isolated or agglomerated, for example. The porous particles are preferably non-aggregated and preferably non-agglomerated.

Aggregated generally means that in the course of the production of the porous particles, primary particles are initially formed and grow together and/or primary particles are linked to one another, for example via covalent bonds, and in this way form aggregates. Primary particles are generally isolated particles. Aggregates or isolated particles can form agglomerates. Agglomerates are a loose accumulation of aggregates or primary particles that are linked to one another, for example, via van der Waals interactions or hydrogen bonds. Agglomerated aggregates can easily be split back into aggregates again by common kneading and dispersing processes. Aggregates can be broken down into the primary particles only partially by such processes, if at all. The presence of the porous particles in the form of aggregates, agglomerates or isolated particles can be visualized for example using conventional scanning electron microscopy (SEM). By contrast, static light scattering methods for determining particle size distributions or particle diameters of matrix particles cannot distinguish aggregates and agglomerates.

The porous particles may have any morphology, i.e. for example, be splintered, flaky, spherical or else needle-shaped, with splintered or spherical particles being preferred.

The morphology may, for example, be characterized by the sphericity ψ or the sphericity S. According to Wadell's definition, the sphericity ψ is the ratio of the surface area of a sphere of equal volume to the actual surface area of a body. In the case of a sphere, ψ is 1. According to this definition, the porous particles have a sphericity ψ of preferably 0.3 to 1.0, particularly preferably of 0.5 to 1.0 and most preferably of 0.65 to 1.0.

The sphericity S is the ratio of the circumference of an equivalent circle with the same area A as the projection of the particle projected onto a surface and the measured circumference U of this projection: S=2\sqrt{πA}/U. In the case of an ideally circular particle, S would have the value 1. For the porous particles the sphericity S is in the range of preferably 0.5 to 1.0 and particularly preferably 0.65 to 1.0, based on percentiles S₁₀ to S₉₀ of the sphericity number distribution. The measurement of the sphericity S is carried out for example with reference to micrographs of individual particles with an optical microscope or, in the case of particles <10 μm, preferably with a scanning electron microscope by graphical evaluation using image analysis software such as ImageJ.

The porous particles preferably have a pore volume accessible to gas of ≥0.2 cm³/g, particularly preferably 0.6 cm 3 /g and most preferably 1.0 cm 3 /g. This is conducive to obtaining high-capacity lithium-ion batteries. The pore volume accessible to gas is determined by gas sorption measurements with nitrogen in accordance with DIN 66134.

The porous particles are preferably open-pored. Open-pored generally means that pores are connected to the surface of particles, for example via channels, and can preferably exchange materials with the environment, in particular exchange gaseous compounds. This can be demonstrated by gas sorption measurements (analysis according to Brunauer, Emmett and Teller, “BET”), i.e. the specific surface area.

The porous particles have specific surface areas of preferably ≥50 m²/g, particularly preferably ≥500 m²/g and most preferably ≥1000 m²/g. The BET surface area is determined according to DIN 66131 (with nitrogen).

The pores of the porous particles can have any diameter, i.e. generally in the range of macropores (>50 nm), mesopores (2 to 50 nm) and micropores (<2 nm). The porous particles may be used in any mixtures of different pore types. Preference is given to using porous particles having at most 30% macropores, based on the total pore volume, particularly preferably porous particles without macropores and especially preferably porous particles having at least 50% pores having an average pore diameter of less than 5 nm. The porous particles particularly preferably have exclusively pores having a pore diameter of less than 2 nm (determination method: pore size distribution according to BJH (gas adsorption) in accordance with DIN 66134 in the mesopore range and according to Horvath-Kawazoe (gas adsorption) in accordance with DIN 66135 in the micropore range; the pore size distribution in the macropore range is evaluated by mercury porosimetry according to DIN ISO 15901-1).

Preference is given to porous particles having a pore volume inaccessible to gas of less than 0.3 cm³/g and particularly preferably less than 0.15 cm³/g. This can also be used to increase the capacity of the lithium-ion batteries. The pore volume inaccessible to gas can be determined using the following formula:

Pore volume inaccessible to gas=1/pure-material density−1/skeletal density.

Here, the pure-material density is a theoretical density of the material, based on the phase composition or the density of the pure substance (density of the material as if it had no closed porosity). Data on pure-material densities can be found by a person skilled in the art, for example, in the Ceramic Data Portal of the National Institute of Standards (NIST, https://srdata.nist.gov/CeramicDataPortal/scd). For example, the pure-material density of silicon oxide SiO₂ is 2.203 g/cm³, that of boron nitride BN is 2.25 g/cm³, that of silicon nitride Si₃N₄ is 3.44 g/cm³ and that of silicon carbide SiC is 3.21 g/cm³. The skeletal density is the actual density of the porous particles (gas-ac-cessible) as determined by helium pycnometry.

For clarification, it should be noted that the porous particles are different from the silicon-containing material. The porous particles act as starting material for producing the silicon-containing material. Generally there is preferably no silicon, more particularly no silicon obtained by deposition of silicon precursors, located in the pores of the porous particles and on the surface of the porous particles.

The silicon-containing material obtained by means of deposition of silicon in pores and on the surface of the porous particles has a volume-weighted particle size distribution with diameter percentiles d₅₀ preferably in a range from 0.5 to 20 μm. The d₅₀ value is preferably at least 1.5 μm, and particularly preferably at least 2 μm. The diameter percentiles d₅₀ are preferably at most 13 μm and particularly preferably at most 8 μm.

The volume-weighted particle size distribution of the silicon-containing material is preferably between the diameter percentiles d₁₀≥0.2 μm and d₉≤20.0 μm, particularly preferably between d₁₀≥0.4 μm and d₉₀≤15.0 μm and most preferably between d₁₀≥0.6 μm to d₉₀≤12.0 μm.

The silicon-containing material has a volume-weighted particle size distribution with diameter percentiles d₁₀ of preferably ≤10 μm, particularly preferably ≤5 μm, especially preferably ≤3 μm and most preferably ≤1 μm. The diameter percentiles d₁₀ are preferably ≥0.2 μm, particularly preferably ≥0.4 μm and most preferably ≥0.6 μm.

The silicon-containing material has a volume-weighted particle size distribution with diameter percentiles d₉₀ of preferably ≥5 μm and particularly preferably ≥10 μm. The diameter percentiles d₉₀ are preferably ≤20.0 μm, particularly preferably ≤15.0 μm and most preferably ≤12.0 μm.

The volume-weighted particle size distribution of the silicon-containing material has a width d₉₀-d₁₀ of preferably ≤15.0 μm, particularly preferably ≤12.0 μm, more preferably ≤10.0 μm, especially preferably ≤8.0 μm and most preferably ≤4.0 μm. The volume-weighted particle size distribution of the silicon-containing material has a width d₉₀-d₁₀ of preferably ≥0.6 μm, particularly preferably ≥0.7 μm and most preferably ≥1.0 μm.

The silicon-containing material is preferably in the form of particles. The particles can be isolated or agglomerated. The silicon-containing active material is preferably non-aggregated and preferably non-agglomerated. The terms isolated, agglomerated and non-aggregated are already defined above with respect to the porous particles. The presence of silicon-containing materials in the form of aggregates or agglomerates can be visualized for example using conventional scanning electron microscopy (SEM).

The silicon-containing material may have any morphology, i.e. for example, be splintered, flaky, spherical or else needle-shaped, with splintered or spherical particles being preferred.

According to Wadell's definition, the sphericity ψ is the ratio of the surface area of a sphere of equal volume to the actual surface area of a body. In the case of a sphere, ψ is 1. According to this definition, the silicon-containing materials have a sphericity ψ of preferably 0.3 to 1.0, particularly preferably of 0.5 to 1.0 and most preferably of 0.65 to 1.0.

The sphericity S is the ratio of the circumference of an equivalent circle with the same area A as the projection of the particle projected onto a surface and the measured circumference U of this projection: S=2\sqrt{πA}/U. In the case of an ideally circular particle, S would have the value 1. For the silicon-containing materials, the sphericity S is in the range of preferably 0.5 to 1.0 and particularly preferably 0.65 to 1.0, based on percentiles S₁₀ to S₉₀ of the sphericity number distribution. The measurement of sphericity S is carried out for example with reference to micrographs of individual particles with an optical microscope or, in the case of particles <10 μm, preferably with a scanning electron microscope by graphical evaluation using image analysis software such as ImageJ.

The cycling stability of lithium-ion batteries can be further increased via the morphology, the material composition, in particular the specific surface area or the internal porosity of the silicon-containing material.

The silicon-containing material preferably comprises 10 to 90% by weight, more preferably 20 to 80% by weight, particularly preferably 30 to 60% by weight and especially preferably 40 to 50% by weight of porous particles, based on the total weight of the silicon-containing material.

The silicon-containing material comprises preferably 10 to 90% by weight, more preferably 20 to 80% by weight, particularly preferably 30 to 60% by weight and especially preferably 40 to 50% by weight silicon obtained via deposition from the silicon precursor, based on the total weight of the silicon-containing material (determination preferably by means of elemental analysis, such as ICP-OES). If the porous particles comprise silicon compounds, for example in the form of silicon dioxide, the above data can be determined in % by weight by subtracting the mass of silicon in the porous particles determined by elemental analysis from the mass of silicon of the silicon-containing material determined by elemental analysis and dividing the result by the mass of the silicon-containing material.

The volume of silicon present in the silicon-containing material, obtained by deposition from the silicon precursor, results from the mass fraction of the silicon obtained via deposition from the silicon precursor in the total mass of the silicon-containing material divided by the density of silicon (2.336 g/cm³).

The pore volume P of the silicon-containing materials results from the sum of gas-accessible and gas-inaccessible pore volumes. According to Gurwitsch, the pore volume accessible to gas of the silicon-containing material can be determined by gas sorption measurements with nitrogen in accordance with DIN 66134.

The pore volume inaccessible to gas of the silicon-containing material can be determined using the formula:

Pore volume inaccessible to gas=1/pure-material density−1/skeletal density.

The pure-material density of a silicon-containing material is a theoretical density that can be calculated from the sum of the theoretical pure-material densities of the components present in the silicon-containing material, multiplied by their respective weight-related percentage of the total material. Pure-material densities are reported in the Ceramic Data Portal of the National Institute of Standards (NIST, https://srdata.nist.gov/CeramicDataPortal/scd). The determination of the skeletal density is described below at the start of the description of the examples. For example, for a silicon-containing material, this results in:

pure-material density=theoretical pure-material density of silicon*proportion of silicon in % by weight+theoretical pure-material density of the porous particles*proportion of the porous particles in % by weight.

The pore volume P of the silicon-containing materials is preferably in the range of 0 to 400% by volume, more preferably in the range of 100 to 350% by volume and particularly preferably in the range of 200 to 350% by volume, based on the volume of the silicon present in the silicon-containing material obtained from the deposition from the silicon precursor.

The porosity of the silicon-containing material can be both accessible and inaccessible to gas. The ratio of the volume of gas-accessible to gas-inaccessible porosity of the silicon-containing material can generally be in the range of 0 (no gas-accessible pores) to 1 (all pores are gas-accessible). The ratio of the volume of gas-accessible to gas-inaccessible porosity of the silicon-containing material is preferably in the range of 0 to 0.8, more preferably in the range of 0 to 0.3 and particularly preferably 0 to 0.1.

The pores of the silicon-containing material may have any diameter, for example in the range of macropores (>50 nm), mesopores (2 to 50 nm) and micropores (<2 nm). The silicon-containing material may also comprise any mixtures of different pore types. Preferably, the silicon-containing material comprises at most 30% macropores, based on the total pore volume, particularly preferred is a silicon-containing material without macropores and especially preferred is a silicon-containing material having at least 50% of pores with a mean pore diameter below 5 nm. Particularly preferably, the silicon-containing material exclusively comprises pores with a diameter of at most 2 nm.

The silicon-containing material has silicon structures which in at least one dimension have structure sizes of preferably at most 1000 nm, more preferably less than 100 nm, particularly preferably less than 5 nm (determination method: scanning electron microscopy (SEM) and/or high resolution transmission electron microscopy (HR-TEM)).

The silicon-containing material preferably comprises silicon layers having a layer thickness of less than 1000 nm, more preferably less than 100 nm, particularly preferably less than 5 nm (determination method: scanning electron microscopy (SEM) and/or high resolution transmission electron microscopy (HR-TEM)). The silicon-containing material can also comprise silicon in the form of particles. Silicon particles have a diameter of preferably at most 1000 nm, more preferably less than 100 nm, particularly preferably less than 5 nm (determination method: scanning electron microscopy (SEM) and/or high resolution transmission electron microscopy (HR-TEM)). The data about the silicon particles preferably relates here to the diameter of the circumference of the particles in the microscope image.

The silicon-containing material has a specific surface area of at most 50 m²/g, preferably less than 30 m²/g, and particularly preferably less than 10 m²/g. The BET surface area is determined according to DIN 66131 (with nitrogen). When using the silicon-containing material as active material in anodes for lithium-ion batteries, SEI formation can be reduced and the initial Coulomb efficiency can be increased.

Furthermore, the silicon deposited from the silicon precursor in the silicon-containing 30 material may comprise dopants, for example selected from the group comprising Li,

Fe, Al, Cu, Ca, K, Na, S, CI, Zr, Ti, Pt, Ni, Cr, Sn, Mg, Ag, Co, Zn, B, P, Sb, Pb, Ge, Bi, rare earths or combinations thereof. Li and/or Sn are preferred. The content of dopants in the silicon-containing material is preferably at most 1% by weight and particularly preferably at most 100 ppm, based on the total weight of the silicon-containing material, which can be determined by ICP-OES.

The silicon-containing material generally exhibits a surprisingly high stability under compressive load and/or shear stress. The pressure stability and the shear stability of the silicon-containing material is demonstrated, for example, by the fact that the silicon-containing material shows no or only slight changes in its porous structure in the SEM under compressive load (for example during electrode compaction) or shear stress (for example during electrode preparation).

The silicon-containing material may generally comprise other components in addition to the porous particles, the silicon deposited from the silicon precursor and the other additional elements. In particular, carbon may also be present. In particular, carbon may be present in the form of thin layers with a layer thickness of at most 1 μm, preferably less than 100 nm, particularly preferably less than 5 nm and especially preferably less than 1 nm (determinable by SEM or HR-TEM). The carbon layers may be present, for example, on the surface of the pores and/or on the outer surface of the silicon-containing material. The sequence of different layers in the silicon-containing material and the number thereof is also arbitrary. For instance, on a porous particle there may be present first a layer of another material different from the material of the porous particle, for example carbon, and on top of this there may be a silicon layer or a layer of silicon particles. Also, on the silicon layer or on the layer of silicon particles, there may in turn be a layer of a further material which may be different from or the same as the material of the porous particles, irrespective of whether there is a further layer of a material different from the material of the porous particles between the porous particle and the silicon layer or the layer consisting of silicon particles.

The silicon-containing material preferably comprises ≤50% by weight, particularly preferably ≤40% by weight and especially preferably ≤20% by weight of additional elements. The silicon-containing material preferably comprises ≥1% by weight, particularly preferably ≥2% by weight and especially preferably ≥3% by weight of additional elements. The percentages by weight refer to the total weight of the silicon-containing material. In an alternative embodiment, the silicon-containing material does not comprise any additional elements.

The invention also relates to a process for producing the silicon-containing material according to the invention by thermally decomposing one or more silicon precursors in the presence of one or more porous particles, thereby depositing silicon in pores and on the surface of the porous particles, the silicon-containing material having a specific surface area of at most 50 m²/g, determined by nitrogen sorption and BET evaluation, characterized in that the porous particles have

a) a mean electrical particle resistance of at least 2 kOhm and

b) a reversible delithiation capacity β of at most 100 mAh/g.

The silicon-containing material can be produced in any reactors commonly used for the deposition of silicon from silicon precursors. Preference is given to reactors selected from the group comprising fluidized bed reactors, rotary kilns, which may be oriented in any arrangement from horizontal to vertical, and fixed-bed reactors, which may be operated as open or closed systems, for example as pressure reactors. Particular preference is given to reactors which enable the porous particles and the silicon-containing material formed during deposition to be mixed homogeneously with the silicon precursors. This is advantageous for the most homogeneous possible deposition of silicon in the pores and on the surface of the porous particles. The most preferred reactors are fluidized bed reactors, rotary kilns or pressure reactors, especially fluidized bed reactors or pressure reactors.

Silicon is generally deposited from the silicon precursors under thermal decomposition. Preferred silicon precursors are selected from the group comprising silicon-hydrogen compounds such as monosilane SiH₄, disilane Si₂H₆ and higher linear, branched or cyclic homologues, neopentasilane Si₅-H₁₂, cyclohexasilane Si₆-H₁₂, chlorine-containing silanes such as trichlorosilane HSiCl₃, dichlorosilane H₂SiCl₂, chlorosilane H₃SiCl, tetrachlorosilane SiCl₄, hexachlorodisilane Si₂Cl₆, and higher linear, branched or cyclic homologues such as 1,1,2,2-tetrachlorodisilane Cl₂HSi—SiHCl₂, chlorinated and partially chlorinated oligo- and polysilanes, methylchlorosilanes such as trichloromethylsilane MeSiCl₃, dichlorodimethylsilane Me₂SiCl₂, chlorotrimethylsilane Me₃SiCl, tetramethylsilane Me₄Si, dichloromethylsilane MeHSiCl₂, chloromethylsilane MeH₂SiCl, methylsilane MeH₃Si, chlorodimethylsilane Me₂HSiCl, dimethylsilane Me₂H₂Si, trimethylsilane Me₃SiH or mixtures of the silicon compounds described. In particular, silicon precursors are selected from the group comprising monosilane SiH₄, disilane Si₂He, trichlorosilane HSiCl₃, dichlorosilane H₂SiCl₂, chlorosilane H₃SiCl, tetrachlorosilane SiCl₄, hexachlorodisilane Si₂Cl₆ and mixtures comprising these silanes.

Furthermore, one or more reactive constituents may be introduced into the reactor. Examples of these are dopants based on boron, nitrogen, phosphorus, arsenic, germanium, iron or nickel-containing compounds. The dopants are preferably selected from the group comprising ammonia NH₃, diborane B₂H₆, phosphane PH₃, germane GeH₄, arsine AsH 3 and nickel tetracarbonyl Ni(CO)4.

Further examples of reactive constituents are hydrogen or hydrocarbons, in particular selected from the group comprising aliphatic hydrocarbons having 1 to 10 carbon atoms, preferably 1 to 6 carbon atoms, such as methane, ethane, propane, butane, pentane, isobutane, hexane, cyclopropane, cyclobutane, cyclopentane, cyclohexane, cycloheptane; unsaturated hydrocarbons having 1 to 10 carbon atoms such as ethylene, acetylene, propylene or butylene; isoprene, butadiene, divinylbenzene, vinylacetylene, cyclohexadiene, cyclooctadiene; cyclic unsaturated hydrocarbons such as cyclopropene, cyclobutene, cyclopentene, cyclohexene, cyclohexadiene, cyclopentadiene, dicyclopentadiene and norbornadiene, aromatic hydrocarbons such as benzene, toluene, p-, m-, o-xylene, styrene (vinylbenzene), ethylbenzene, diphenylmethane or naphthalene; other aromatic hydrocarbons such as phenol, o-, m-, p-cresol, cymene, nitrobenzene, chlorobenzene, pyridine, anthracene and phenanthrene, myrcene, geraniol, thioterpineol, norbornane, borneol, isoborneol, bornane, camphor, limonene, terpinene, pinene, pinane, carene, phenol, aniline, anisole, furan, furfural, furfuryl alcohol, hydroxymethylfurfural, bishydroxymethylfuran and mixed fractions comprising a variety of such compounds, for example from natural gas condensates, petroleum distillates, coke oven condensates, mixed fractions from the product streams of a fluid catalytic cracker (FCC), steam cracker or a Fischer-Tropsch synthesis plant, or more generally hydrocarbonaceous material streams from wood, natural gas, petroleum and coal processing.

The process is preferably carried out in an inert gas atmosphere, for example in a nitrogen or argon atmosphere.

In all other respects, the process can be carried out in the conventional manner commonly used for the deposition of silicon from silicon precursors, if necessary with routine adjustments customary to those skilled in the art.

The invention further relates to the use of the silicon-containing material according to the invention as active material in anode materials for anodes of lithium-ion batteries and the use of the anodes according to the invention for producing lithium-ion batteries.

The anode material is preferably based on a mixture comprising the silicon-containing material according to the invention, one or more binders, optionally graphite as further active material, optionally one or more further electrically conducting components and optionally one or more additives.

The invention further relates to an anode material comprising the silicon-containing material according to the invention, one or more binders, optionally graphite as further active material, optionally one or more further electrically conducting components and optionally one or more additives.

By using other electrically conducting components in the anode material, the contact resistances within the electrode and between the electrode and current collector can be reduced, which improves the current-carrying capacity of the lithium-ion battery. Preferred further electrically conducting components are conductive carbon black, carbon nanotubes or metallic particles, for example copper.

The primary particles of conductive carbon black preferably have a volume-weighted particle size distribution between the diameter percentiles d₁₀=5 nm and d₉₀=200 nm. The primary particles of conductive carbon black can also be branched like a chain and form structures up to pm in size. Carbon nanotubes preferably have a diameter of 0.4 to 200 nm, more preferably 2 to 100 nm and most preferably 5 to 30 nm. The metallic particles have a volume-weighted particle size distribution which is between the diameter percentiles d=5 nm and d₉₀=800 nm.

The anode material preferably comprises 0 to 95% by weight, particularly preferably 0 to 40% by weight and most preferably 0 to 25% by weight of one or more further electrically conducting components, based on the total weight of the anode material.

The silicon-containing material may be present in the anodes for lithium-ion batteries at preferably 5 to 100% by weight, more preferably 30 to 100% by weight and most preferably 60 to 100% by weight, based on the total active material present in the anode material.

Preferred binders are polyacrylic acid or alkali metal salts thereof, especially lithium or sodium salts, polyvinyl alcohols, cellulose or cellulose derivatives, polyvinylidene fluoride, polytetrafluoroethylene, polyolefins, polyimides, especially polyamide-imides, or thermoplastic elastomers, especially ethylene-propylene-diene terpolymers. Particular preference is given to polyacrylic acid, polymethacrylic acid or cellulose derivatives, especially carboxymethyl cellulose. The alkali metal salts, in particular lithium or sodium salts, of the aforementioned binders are also particularly preferred. Most preferred are the alkali metal salts, especially lithium or sodium salts, of polyacrylic acid or polymethacrylic acid. All or preferably a proportion of the acid groups of a binder may be present in the form of salts. The binders have a molar mass of preferably 100 000 to 1 000 000 g/mol. Mixtures of two or more binders can also be used.

The graphite used can generally be natural or synthetic graphite. The graphite particles preferably have a volume-weighted particle size distribution between the diameter percentiles d₁₀>0.2 μm and d₉₀<200 μm.

Examples of additives are pore formers, dispersants, leveling agents or dopants, for example elemental lithium.

Preferred formulations for the anode material preferably comprise 5 to 95% by weight, in particular 60 to 90% by weight, of the silicon-containing material; 0 to 90% by weight, in particular 0 to 40% by weight, of further electrically conducting components; 0 to 90% by weight, in particular 5 to 40% by weight, of graphite; 0 to 25% by weight, in particular 5 to 20% by weight, of binder; and optionally 0 to 80% by weight, in particular 0.1 to 5% by weight, of further additives, where the percentages by weight refer to the total weight of the anode material and the proportions of all constituents of the anode material add up to 100% by weight.

The invention further relates to an anode which comprises a current collector which is coated with the anode material according to the invention. The anode is preferably used in lithium-ion batteries.

The constituents of the anode material can be processed into an anode ink or paste, for example, in a solvent, preferably selected from the group comprising water, hexane, toluene, tetrahydrofuran, N-methylpyrrolidone, N-ethylpyrrolidone, acetone, ethyl acetate, dimethyl sulfoxide, dimethylacetamide and ethanol and mixtures of these solvents, preferably using rotor-stator machines, high-energy mills, planetary kneaders, agitator bead mills, vibrating plates or ultrasonic devices.

The anode ink or paste preferably has a pH of 2 to 7.5 (determined at 20° C., for example with the WTW pH 340i pH meter with SenTix RJD probe).

For example, the anode ink or paste can be knife-coated onto a copper foil or other current collector. Other coating methods may also be used in accordance with the invention, such as spin coating, roller, dip or slot coating, brushing or spraying.

Before the copper foil is coated with the anode material according to the invention, the copper foil may be treated with a commercially available primer, for example based on polymer resins or silanes. Primers can lead to improvement in adhesion to the copper, but themselves generally have practically no electrochemical activity.

The anode material is preferably dried to constant weight. The drying temperature depends on the components and the solvent used. The drying temperature is preferably between 20° C. and 300° C., particularly preferably between 50° C. and 150° C.

The layer thickness, i.e. the dry layer thickness of the anode coating, is preferably from 2 μm to 500 μm, particularly preferably from 10 μm to 300 μm.

Finally, the electrode coatings may be calendered to achieve a defined porosity. The electrodes produced in this way preferably have porosities of 15 to 85%, which may be determined by mercury porosimetry according to DIN ISO 15901-1. Preferably, 25 to 85% of the pore volume that can be determined in this way is provided by pores that have a pore diameter of 0.01 to 2 μm.

The invention further relates to lithium-ion batteries comprising a cathode, an anode, two electrically conducting connections to the electrodes, a separator and an electrolyte with which the separator and the two electrodes are impregnated, and a housing accommodating the parts specified, characterized in that the anode comprises silicon-containing material according to the invention.

In the context of this invention, the term lithium-ion battery also includes cells. Cells generally comprise a cathode, an anode, a separator and an electrolyte. In addition to one or more cells lithium-ion batteries preferably also contain a battery management system. Battery management systems are generally used to control batteries, for example using electronic circuits, in particular for detecting the state of charge, for deep discharge protection or overcharge protection.

Preferred cathode materials used may be lithium cobalt oxide, lithium nickel oxide, lithium nickel cobalt oxide (doped or undoped), lithium manganese oxide (spinel), lithium nickel cobalt manganese oxides, lithium nickel manganese oxides, lithium iron phosphate, lithium cobalt phosphate, lithium manganese phosphate, lithium vanadium phosphate or lithium vanadium oxides.

The separator is preferably an electrically insulating membrane permeable to ions, preferably composed of polyolefins, for example polyethylene (PE) or polypropylene (PP), or polyester or corresponding laminates. The separator can alternatively consist of or be coated with glass or ceramic materials, as is common in battery manufacturing. As is known, the separator separates the first electrode from the second electrode and thus prevents electronically conducting connections between the electrodes (short circuit).

The electrolyte is preferably a solution comprising one or more lithium salts (=conducting salt) in an aprotic solvent. Conducting salts are preferably selected from the group comprising lithium hexafluorophosphate, lithium hexafluoroarsenate, lithium perchlorate, lithium tetrafluoroborate, lithium imides, lithium methides, LiCF₃SO₃, LiN(CF₃SO₂) and lithium borates. The concentration of the conducting salt, based on the solvent, is preferably between 0.5 mol/l and the solubility limit of the relevant salt. It is particularly preferably from 0.8 to 1.2 mol/l.

Examples of solvents that can be used are cyclic carbonates, propylene carbonate, ethylene carbonate, fluoroethylene carbonate, dimethyl carbonate, diethyl carbonate, ethyl methyl carbonate, dimethoxyethane, diethoxyethane, tetrahydrofuran, 2-methyltetrahydrofuran, gamma-butyrolactone, dioxolane, acetonitrile, organic carbonic acid esters or nitriles, individually or as mixtures thereof.

The electrolyte preferably contains a film former, such as vinylene carbonate or fluoroethylene carbonate. As a result, a significant improvement in the cycle stability of the anodes containing the silicon-containing material according to the invention can be achieved. This is mainly attributed to the formation of a solid electrolyte interphase on the surface of active particles. The proportion of the film former in the electrolyte is preferably between 0.1 and 20.0% by weight, particularly preferably between 0.2 and by weight and most preferably between 0.5 and 10% by weight.

In order to match the actual capacities of the electrodes of a lithium-ion cell as optimally as possible, it is advantageous to balance the materials for the positive and negative electrodes in terms of quantity. In this context, it is of particular importance that during the first or initial charge/discharge cycle of secondary lithium-ion cells (so-called formation), a covering layer forms on the surface of the electrochemically active materials in the anode. This top layer is referred to as “Solid Electrolyte Interphase” (SEI) and generally consists primarily of electrolyte decomposition products and a certain amount of lithium, which is accordingly no longer available for further charge/discharge reactions. The thickness and composition of the SEI depend on the type and quality of the anode material used and the electrolyte solution used.

In the case of graphite, the SEI is particularly thin. On graphite, there is typically a loss of 5% to 35% of the mobile lithium in the cell in the first charging step. Accordingly, the reversible capacity of the battery also decreases.

In the case of anodes with the silicon-containing material according to the invention, there is a loss of mobile lithium in the first charging step of preferably at most 30%, particularly preferably at most 20% and most preferably at most 10%, which is significantly below the values of the prior art described, for example in U.S. Pat. No. 10,147,950 B1, for silicon-containing composite anode materials.

The lithium-ion battery according to the invention can be produced in all the usual forms, for example in wound, folded or stacked form.

All substances and materials used to produce the lithium-ion battery according to the invention, as described above, are known. The manufacture of the parts of the battery according to the invention and the assembly thereof to form the battery according to the invention are carried out according to the methods known in the field of battery production.

The inventive silicon-containing material is characterized by significantly improved electrochemical behavior and results in lithium-ion batteries with high volumetric capacities and excellent application properties. The silicon-containing material according to the invention is permeable to lithium ions and electrons and thus enables charge transport. The amount of SEI in lithium-ion batteries can be reduced to a large extent using the silicon-containing material according to the invention. In addition, due to the design of the silicon-containing material according to the invention, the SEI no longer detaches from the surface of the silicon-containing material according to the invention, or at least detaches to a much lesser extent. All this results in high cycle stability of corresponding lithium-ion batteries. Fading and trapping can be minimized. Furthermore lithium-ion batteries according to the invention show a low initial and continuous loss of lithium available in the cell and thus high Coulomb efficiencies.

The following examples serve to further elucidate the invention described here.

Scanning Electron Microscopy (SEM/EDX):

The microscope analyses were carried out using a Zeiss Ultra 55 scanning electron microscope and an energy-dispersive Oxford X-Max 80N x-ray spectrometer. Before analysis, the samples underwent vapor deposition of carbon, using a Safematic Compact Coating Unit 010/HV, to prevent charging phenomena. Cross-sections of the silicon-containing materials were produced with a Leica TIC 3X ion cutter at 6 kV.

Inorganic/Elemental Analysis:

The C contents were determined using a Leco CS 230 analyzer and a Leco TCH-600 analyzer was used to determine oxygen and nitrogen contents. The qualitative and quantitative determination of other elements was carried out by ICP (inductively-coupled plasma) emission spectrometry (Optima 7300 DV, Perkin Elmer). For this purpose, the samples were subjected to acid digestion (HF/HNO₃) in a microwave (Microwave 3000, from Anton Paar). The ICP-OES determination is guided by ISO 11885 “Water quality - Determination of selected elements by inductively coupled plasma atom emission spectrometry (ICP-OES) (ISO 11885:2007); German version EN ISO 11885:2009”, which is used for analysis of acidic, aqueous solutions (for example acidified drinking water, wastewater and other water samples, aqua regia extracts of soils and sediments).

Particle Size Determination:

The particle size distribution was determined in accordance with ISO 13320 by means of static laser scattering with a Horiba LA 950. In the preparation of the samples, particular attention must be paid to the dispersing of the particles in the measurement solution in order not to measure the size of agglomerates rather than individual particles. For the materials examined here, these were dispersed in ethanol. For this purpose, the dispersion, prior to the measurement, if required, was treated with 250 W ultrasound in a Hielscher model UIS250v ultrasound laboratory instrument with

LS24d5 sonotrode for 4 minutes.

BET Surface Area Measurement:

The specific surface area of the materials was measured via gas adsorption with nitrogen using a Sorptomatic 199090 instrument (Porotec) or SA-9603MP instrument (Horiba) by the BET method (determination in accordance with DIN ISO 9277:2003-05 using nitrogen).

Skeletal Density:

The skeletal density, i.e, the density of the porous solid based on the volume of only the pore spaces accessible to gas from the outside, was determined by helium pycnometry in accordance with DIN 66137-2.

Gas-Accessible Pore Volume:

The gas-accessible pore volume according to Gurwitsch was determined by gas sorption measurements with nitrogen in accordance with DIN 66134.

Determination of the reversible delithiation capacity β:

The determination of the capacity of the porous particles or of the silicon-containing materials is carried out in a button half-cell (type CR2032, Hohsen Corp.). For this purpose, an electrode is produced from the porous particles or the silicon-containing material and binder, optionally graphite, optionally further electrically conducting components and optionally additives and installed against a lithium counter-electrode (Rockwood Lithium, thickness 0.5 mm, diameter=15 mm). The working electrode based on the silicon-containing material corresponds to the positive electrode in this cell construction. Metallic lithium is used as the counter-electrode, which represents the negative electrode. A glass fiber filter paper (Whatman, GD Type D) saturated with 120 μl of electrolyte is used as the separator (Dm=16 mm). The electrolyte used is a 1.0 molar solution of lithium hexafluorophosphate in a 1:4 (v/v) mixture of fluoroethylene carbonate and diethyl carbonate. The cell is generally constructed in a glove box (<1 ppm of H₂O and O₂). The water content of the dry matter of all starting materials is preferably below 20 ppm.

First, the half-cell is converted into the discharged state by being discharged by the cc-method (constant current) using a constant current, which corresponds to a rate of C/25 based on the theoretical capacity of the silicon-containing material (theoretical capacity: silicon% by weight * 3579 mAh/g; rate: C/25 corresponds to a charge/discharge over a period of 25 h), until the voltage limit of 0.005 V is reached. Here, the active material is lithiated.

The reversible delithiation capacity β of the anode coating is determined by subsequently charging the button half-cell produced and discharged in this way with C/25 until the voltage limit of 1.5 V is reached.

The electrochemical measurements are carried out at 20° C.

Determination of the Mean Electrical Particle Resistance:

to measure the electrical resistance of individual particles smaller than 100 μm, a Shimadzu Microcompression Tester MCT211 was equipped with a flat copper indenter which, together with the sample holder, was connected to a KEITHLEY 2602 dual source meter. The resistance values of the individual particles scatter due to the different geometry of the different particles. For this reason, the mean value of the electrical resistance of at least 20 individual particles is determined for each product batch. Statistical analysis using a t-test [one-sample test, Student: The Probable Error of a Mean. In: Biometrika. Volume 6, No. 1 Mar. 1908, pp. 1-259] then makes it possible to determine significant differences between the mean values of different product batches at a defined confidence level of, for example, 95%.

### EXAMPLE 1

Porous Particles of Silicon Dioxide:

493 ml of ethanol and 308 ml of water were initially charged in a wide-necked 1 I Duran glass bottle. 30.18 g of tetraethoxysilane (TEOS) were added to this mixture at room temperature and dissolved with stirring. The solution was temperature-controlled to 15° C. and a further 30.18 g of TEOS were added by means of a dropping funnel over a period of 45 minutes. The solution slowly became cloudy, resulting in a precipitate. The reaction mixture was stirred at 15° C. for a further 4 h. Then the precipitate was suction filtered and washed four times with water and ethanol. The white powder obtained in this way was dried in a drying cabinet at 80° C. for 4 h. The crude product (18.68 g) was heated to 400° C. in a boat in a tube furnace at a heating rate of 2° C./min. The next holding level of 600° C. was approached at 10° C./min and held for 4 h. The atmosphere of the furnace was adjusted via an argon flow of 12 l/h during the entire reaction and 3 l/h during the cooling phase until the tube was emptied. 13.74 g (73.6%) of porous SiO₂ particles were obtained.

Reversible delithiation capacity β: 8 mAh/g

BET: 1270 m²/g

Particle size distribution (PSD): D₅₀=5.4 μm, span 0.77

Total pore volume: 0.8 cm₃/g

Mean electrical particle resistance: 240 000 kOhm

### EXAMPLE 2

Silicon-Containing Material:

A tubular reactor was charged with 3.0 g of the porous silicon dioxide particles (specific surface area=1070 m²/g, pore volume=0.6 cm³/g) from Example 1 in a quartz glass boat. After inertization with nitrogen, the reactor was heated to 410° C. After reaching the reaction temperature, the reactive gas (10% SiH₄ in N₂, 10 Nl/h) was passed through the reactor for 5.8 h. The reactor was then purged with inert gas before the product was annealed at 500° C. for 1 hour. Before removal from the reactor, the product was cooled to room temperature under inert gas.

BET surface area: 29 m²/g

PSD: D_{50/}=5.4 μm, span 0.77

deposited Si content: 35% by weight

Reversible delithiation capacity β: 1245 mAh/g

Initial Coulomb efficiency: 92%

### COMPARATIVE EXAMPLE 3

Silicon-Containing Material:

A tubular reactor was charged with 3.0 g of a mesoporous silicon dioxide matrix (specific surface area=360 m²/g, pore volume=1.1 cm³/g, Polygoprep™ 100-12 from Macherey-Nagel, mean particle electrical resistance 210 000 kOhm, reversible capacity β=8 mAh/g). After inertization with nitrogen, the reactor was heated to 410° C. After reaching the reaction temperature, the reactive gas (10% SiH₄ in N₂, 10 Nl/h) was passed through the reactor for 5 h. The reactor was then purged with inert gas before the product was annealed at 500° C. for 1 hour. Before removal from the reactor, the product was cooled to room temperature under inert gas.

BET: 214 m²/g

PSD: D₅₀=14 μm, span 0.8

Deposited Si content: 30% by weight

Reversible delithiation capacity β: 1068 mAh/g

Initial Coulomb efficiency: 89%

### EXAMPLE 4

Anode comprising silicon-containing material from Example 2 and electrochemical testing in a lithium-ion battery:

29.71 g of polyacrylic acid (dried at 85° C. to constant weight; Sigma-Aldrich, Mw ˜450 000 g/mol) and 756.60 g of deionized water were agitated by means of a shaker (290 1/min) for 2.5 h until dissolution of the polyacrylic acid was complete. Lithium hydroxide monohydrate (Sigma-Aldrich) was added in portions to the solution until the pH was 7.0 (measured by WTW pH 340i pH meter and SenTix RJD probe). The solution was then mixed by means of a shaker for a further 4 h. 3.87 g of the neutralized polyacrylic acid solution and 0.96 g of graphite (Imerys, KS6L C) were initially charged in a 50 ml vessel and mixed in a planetary mixer (SpeedMixer, DAC 150 SP) at 2000 rpm. Subsequently, 3.40 g of the silicon-containing material according to the invention from Example 2 were stirred in at 2000 rpm for 1 minute. 1.21 g of an 8 percent conductive carbon black dispersion and 0.8 g of deionized water were then added and incorporated at 2000 rpm in the planetary mixer.

Dispersion was then carried out in the dissolver for 30 min at 3000 rpm at a constant The ink was degassed again in the planetary mixer at 2500 rpm for 5 minutes under vacuum.

The finished dispersion was then applied to a copper foil having a thickness of 0.03 mm (Schlenk metal foils, SE-Cu58) using a film-drawing frame with a gap height of mm (Erichsen, model 360). The anode coating thus produced was then dried at and 1 bar air pressure for 60 min. The average basis weight of the dry anode coating was 3.0 mg/cm² and the coating density 0.7 g/cm³.

The electrochemical studies were conducted on a button cell (CR2032 type, Hohsen Corp.) in a 2-electrode arrangement. The electrode coating was used as counterelectrode or negative electrode (Dm=15 mm); a coating based on lithium-nickel-manganese-cobalt oxide 6:2:2 having a content of 94.0% and average basis weight of 15.9 mg/cm² (obtained from SEI) was used as working electrode or positive electrode (Dm=15 mm). A glass fiber filter paper (Whatman, GD Type D) saturated with 60 μl of electrolyte was used as the separator (Dm=16 mm). The electrolyte used consisted of a 1.0 molar solution of lithium hexafluorophosphate in a 1:4 (v/v) mixture of fluoroethylene carbonate and diethyl carbonate. The cell was constructed in a glove-box (<1 ppm H₂O, O₂); the water content in the dry matter of all components used was below 20 ppm.

The electrochemical testing was conducted at 20° C. The cells were charged by the cc/cv method (constant current/constant voltage) with a constant current of 5 mA/g (corresponding to C/25) in the first cycle and of 60 mA/g (corresponding to C/2) in the subsequent cycles and, on attainment of the voltage limit of 4.2 V, at constant voltage until the current went below 1.2 mA/g (corresponding to C/100) or 15 mA/g (corresponding to C/8). The cell was discharged by the cc method (constant current) with a constant current of 5 mA/g (corresponding to C/25) in the first cycle and of mA/g (corresponding to C/2) in the subsequent cycles until attainment of the voltage limit of 2.5 V. The specific current chosen was based on the weight of the coating of the positive electrode. The electrodes were selected in such a way that a capacitance ratio of cathode:anode=1:1.2 was set.

The following test results were obtained with the full lithium-ion battery cell of Example 4:
reversible specific capacity of the negative electrode in the second cycle:

600 mAh/g (4.2-2.5 V); 534 mAh/g (4.2-3.0 V)
number of cycles with 80% capacity retention:

302 charge/discharge cycles.

### COMPARATIVE EXAMPLE 5

Anode with silicon-containing material from Comparative Example 3 and electrochemical testing in a lithium-ion battery:

With the non-inventive silicon-containing material of Comparative Example 3, an anode was produced as described in Example 4. The anode was installed in a lithiumion battery as described in Example 4 and subjected to testing by the same procedure.

The following test results were obtained with the full lithium-ion battery cell of

### COMPARATIVE EXAMPLE 5

reversible specific capacity of the negative electrode in the second cycle:

520 mAh/g (4.2-2.5 V); 490 mAh/g (4.2-3.0 V)
number of cycles with 80% capacity retention:

35 charge/discharge cycles.

### EXAMPLE 6

Microporous Boron Nitride as Porous Particles:

3.36 g of boric acid and 13.68 g of dicyandiamide were dissolved in 300 ml of distilled water at room temperature. The solution was then heated to 100° C. and evaporated with stirring until a white crystalline solid (16.79 g) was obtained. A quartz glass boat was then filled with 8.15 g of the intermediate product thus obtained and placed in a tube furnace. This was heated under a stream of forming gas (5% H₂ in N₂, 12 Nl/h) to 975° C. at a rate of 10 K/min. After reaching the target temperature, the gas stream was switched to CO₂ (3 Nl/h) and maintained for 5 h. Finally, the mixture was passively cooled to room temperature under a forming gas stream (3 NI/h). This gave 0.5 g of white solid.

BET surface area: 1006 m²/g

Total pore volume: 0.56 cm³/g

Reversible delithiation capacity β: 5 mAh/g

Mean electrical particle resistance: 72 740 kOhm

PSD: D₅₀=6.8 μm. Span 0.81

### EXAMPLE 7

Silicon-Containing Material with the Porous Particles from Example 6

A tubular reactor was charged with 3.0 g of the porous BN particles from Example 6 in a quartz glass boat. After inertization with nitrogen, the reactor was heated to 410° C. After reaching the reaction temperature, the reactive gas (10% SiH₄ in N₂, 10 Nl/h) was passed through the reactor for 5.2 h. The reactor was then purged with inert gas before the product was annealed at 500° C. for 1 hour. Before removal from the reactor, the product was cooled to room temperature under inert gas.

BET surface area: 14 m²/g

PSD: D₅₀=6.8 μm, span 0.81

Deposited Si content: 35% by weight

Reversible delithiation capacity β: 1210 mAh/g

### EXAMPLE 8

Anode with the silicon-containing material from Example 7 and electrochemical testing in a lithium-ion battery:

With the inventive silicon-containing material of Example 7, an anode was produced as described in Example 4. The anode was installed in a lithium-ion battery as described in Example 4 and subjected to testing by the same procedure.

The following test results were obtained with the full lithium-ion battery cell of Example 8:
reversible specific capacity of the negative electrode in the second cycle:

740 mAh/g (4.2-2.5 V); 657 mAh/g (4.2-3.0 V)
number of cycles with 80% capacity retention:

280 charge/discharge cycles.

### COMPARATIVE EXAMPLE 9

Silicon-Containing Material Based on a Porous Carbon as Porous Particles:

A tubular reactor was charged with 3.0 g of the porous carbon (specific surface area=1189 m²/g, pore volume=0.65 cm³/g, mean particle electrical resistance 1.2 kOhm, reversible capacity β=389 mAh/g) in a quartz glass boat. After inertization with nitrogen, the reactor was heated to 410° C. After reaching the reaction temperature, the reactive gas (10% SiH₄ in N₂, 10 Nl/h) was passed through the reactor for 5.2 h. The reactor was then purged with inert gas before the product was annealed at 500° C. for 1 hour. Before removal from the reactor, the product was cooled to room temperature under inert gas.

BET surface area: 32 m²/g

PSD: D₅₀=3.9 μm, span 0.86

Deposited Si content: 38% by weight

Reversible delithiation capacity β: 1130 mAh/g

### COMPARATIVE EXAMPLE 10

Anode with the Silicon-Containing Material from Comparative Example 9 and Electrochemical Testing in a Lithium-Ion Battery:

With the non-inventive silicon-containing material of Comparative Example 9, an anode was produced as described in Example 4. The anode was installed in a lithium-ion battery as described in Example 4 and subjected to testing by the same procedure.

The Following Test Results were Obtained with the Full Lithium-Ion Battery Cell of Comparative 10:
reversible specific capacity of the negative electrode in the second cycle:

580 mAh/g (4.2-2.5 V); 464 mAh/g (4.2-3.0 V)
number of cycles with ≥80% capacity retention:

174 charge/discharge cycles.

TABLE 1
Electrochemical characteristics from full-cell measurements of the Si-
containing active materials:

| | | | Anode discharge | Number of cycles |
|---|---|---|---|---|
| | | | capacity | with |
| | | | after cycle 1 | ≥80% capacity |
| | Porosity | Base material | [mAh/g] | retention |
| Ex. 4 | Micro | SiO₂ | 600 | 302 |
| Comp. | Meso | SiO₂ | 520 | 35 |
| Ex. 5 | | | | |
| Ex. 8 | Micro | BN | 740 | 280 |
| Comp. | Micro | C | 580 | 174 |
| Ex. 10 | | | | |

1-16. (canceled)

17. A silicon-containing material, comprising:
wherein said silicon-containing material is based on one or more porous particles and silicon;
wherein the silicon is disposed in pores and on the surface of the one or more porous particles and the silicon-containing material has a specific surface area of at most 50 m²/g, determined by nitrogen sorption and BET evaluation; and
wherein the one or more porous particles have
a) a mean electrical particle resistance of at least 2 kOhm, and
b) a reversible delithiation capacity β of at most 100 mAh/g.

18. The silicon-containing material of claim 17, wherein the one or more porous particles are based on one or more materials selected from the group comprising oxides selected from the group comprising silicon dioxide, aluminum oxide, silicon-aluminum mixed oxides, magnesium oxide, lead oxides and zirconium oxide, carbides selected from the group comprising silicon carbides and boron carbides, nitrides selected from the group comprising silicon nitrides and boron nitrides, and other ceramic materials.

19. The silicon-containing material of claim 17, wherein the one or more porous particles are based on a ceramic material of the general composition AlₐB_{b}C_{c}Mg_{d}NₑO_{f}Si_{g} where 0 £ a, b, c, d, e, f, g≤1;
wherein at least two coefficients a to g are >0 and a*3+b*3+c*4+d*2+g*4³ e*3+f*2, comprising the ceramic materials selected from the group comprising:
non-stoichiometric boron nitrides BN_{z} where z=0.2 to 1,
non-stoichiometric carbon nitrides CN_{z} where z=0.1 to 4/3,
boron carbonitrides BₓCN_{z} where x=0.1 to 20 and z=0.1 to 20, where x*3+4 ³ z*3,
boron nitride oxides BN_{z}Oᵣ where z=0.1 to 1 and r=0.1 to 1, where 3 ³ r*2 +z*3,
boron carbonitride oxides BₓCN_{z}Oᵣ where x=0.1 to 2, z=0.1 to 1 and r=0.1 to 1, where x*3+4 ³ r*2+z*3,
silicon carbon oxides SiₓCO_{z} where x=0.1 to 2 and z=0.1 to 2, where x*4+4 ³ z*2,
silicon carbonitrides SiₓCN_{z} where x=0.1 to 3 and z=0.1 to 4, where x*4+4 ³ z*3,
silicon boron carbonitrides Si_{w}BₓCN_{z} where w=0.1 to 3, x=0.1 to 2 and z =0.1 to 4, where w*4+x*3+4 ³ z*3,
silicon boron carbon oxides Si_{w}BₓCO_{z} where w=0.10 to 3, x=0.1 to 2 and z=0.1 to 4, where w*4+x*3+4 ³ z*2,
silicon boron carbonitride oxides SiᵥB_{w}CNₓO_{z} where v=0.1 to 3, w=0.1 to 2, x=0.1 to 4 and z=0.1 to 3, where v*4 +w*3+4 ³ x*3+z*2, and
aluminum boron silicon carbonitride oxides AlᵤBᵥSiₓCN_{w}O_{z} where u=0.1 to 2, v=0.1 to 2, w=0.1 to 4, x=0.1 to 2 and z=0.1 to 3, where u*3+v*3+x*4+4 ³ w*3+z*2.

20. The silicon-containing material of claim 17, wherein the one or more porous particles have a density determined by helium pycnometry of 0.1 to 7 g/cm^{3.}

21. The silicon-containing material of claim 17, wherein the one or more porous particles have a volume-weighted particle size distribution with diameter percentiles d₅₀ from 0.5 to 20 μm.

22. The silicon-containing material of claim 17, wherein the silicon-containing material has a volume-weighted particle size distribution with diameter percentiles d₅₀ from 0.5 to 20 μm.

23. The silicon-containing material of claim 17, wherein the silicon-containing material has at most 30% macropores, based on the total pore volume.

24. The silicon-containing material of claim 17, wherein the silicon-containing material has one or more 50% of the pores with a diameter of at most 5 nm.

25. The silicon-containing material of claim 17, wherein the silicon-containing material comprises at least 30% by weight silicon, obtained by thermal decomposition of silicon precursor.

26. The silicon-containing material of claim 17, wherein the silicon-containing material has a total pore volume which is at least as large as the volume of the silicon deposited via thermal decomposition of silicon precursor.

27. The silicon-containing material of claim 17, wherein the silicon is present in pores and on the outer surface of the one or more porous particles in the form of layers or in the form of layers formed from silicon particles having a thickness of at most 1 μm.

28. A process of producing silicon-containing material, comprising:
thermally decomposing one or more silicon precursors in the presence of one or more porous particles, thereby depositing silicon in pores and on the surface of the one or more porous particles, wherein the silicon-containing material has a specific surface area of at most 50 m^{2 /}g, determined by nitrogen sorption and BET evaluation, and wherein the one or more porous particles have
a) a mean electrical particle resistance of at least 2 kOhm, and
b) a reversible delithiation capacity 0 of at most 100 mAh/g.

29. The process of claim 28, wherein silicon is deposited from the silicon precursors in a reactor selected from the group comprising fluidized bed reactors, rotary kilns oriented from horizontal to vertical, open or closed fixed-bed reactors, and pressure reactors.

30. An anode material, comprising:
a silicon-containing material, wherein the silicon-containing material is based on one or more porous particles and silicon;
wherein the silicon is disposed in pores and on the surface of the one or more porous particles and the silicon-containing material has a specific surface area of at most 50 m²/g, determined by nitrogen sorption and BET evaluation;
wherein the one or more porous particles have
a) a mean electrical particle resistance of at least 2 kOhm, and
b) a reversible delithiation capacity β of at most 100 mAh/g;
wherein the anode material comprises 5 to 95% by weight of the silicon-containing material, 0 to 90% by weight of one or more further electrically conducting components, 0 to 90% by weight of graphite, 0 to 25% by weight of binder and 0 to 80% by weight of further additives, wherein the percentages by weight refer to the total weight of the anode material and the proportions of all constituents of the anode material add up to 100% by weight.

31. The anode material of claim 30, wherein the anode material is used in an anode comprising a current collector that is coated with the anode material.

32. The anode material of claim 30, wherein the anode material is used in a lithium-ion battery;
wherein the lithium-ion battery comprises a cathode, an anode, two electrically conducting connections to the electrodes, a separator and an electrolyte with which the separator and the two electrodes are impregnated, and a housing; and
wherein the anode of the lithium-ion battery comprises silicon-containing material.
